(19) United States
(12) Patent Application Publication
(10) Pub. No.: US 2025/0364348 A1
(43) Pub. Date: Nov. 27, 2025

(54) METHOD OF DETERMINING A TEMPERATURE OF A TRANSISTOR, TRANSISTOR DRIVER DEVICE AND SYSTEM

(71) Applicant: Infineon Technologies Austria AG, Villach (AT)

(72) Inventors: Hao ZHANG, Shanghai (CN); Ziqing ZHENG, Shanghai (CN)

(21) Appl. No.: 19/211,570

(22) Filed: May 19, 2025

(30) Foreign Application Priority Data
May 22, 2024 (DE) 102024114320.7

(51) Int. Cl. H01L 23/34; G01K 7/01

(52) U.S. Cl. CPC H01L 23/34; G01K 7/01; G01K 2217/00

(57) ABSTRACT

A method of determining a temperature of a transistor is provided. The method includes providing a current pulse of a predefined length and a predefined current magnitude to a control terminal of the transistor, and measuring a voltage at the control terminal. The temperature of the transistor is then determined based on the measured voltage.

### CROSS-REFERENCE TO RELATED APPLICATION

This application claims priority to Germany Patent Application No. 102024114320.7 filed on May 22, 2024, the content of which is incorporated by reference herein in its entirety.

### TECHNICAL FIELD

The present application relates to methods of determining a temperature of a transistor, a transistor driver device capable of determining the temperature of a transistor and a system including such a driver device.

### BACKGROUND

In various circumstances, it may be desirable to measure or estimate the temperature of a transistor, for example the so-called junction temperature, e.g., the temperature of a chip including the transistor, for example inside a package. Providing a temperature sensor on the package may lead to delays and imprecisions in the measured temperature, as the temperature measured may not correctly reflect the temperature of the transistor itself.

One example of an application where measuring the temperature is desirable is overtemperature protection of transistors, e.g., detecting if the temperature of the transistor becomes too high and then introducing countermeasures like turning the transistor off. Other applications may include temperature dependent calibrations.

### SUMMARY

According to an implementation, a method of determining a temperature of a transistor is provided, including: providing a current pulse of predefined length and predefined current magnitude to a control terminal of a transistor, measuring a voltage at the control terminal, and determining the temperature of the transistor based on the measured voltage.

In another implementation, a transistor driver device is provided, including: a driver circuit configured to provide a current pulse of predefined length and predefined current magnitude at a driver output terminal, a voltage measurement device configured to measure a voltage at the driver output terminal, and an evaluation device configured to determine a temperature of a transistor based on the measured voltage.

A system including such a transistor driver device and the transistor is also provided, where the driver output terminal is coupled to a control terminal of the transistor.

The above summary merely gives a brief overview over some implementations and is not to be construed as limiting, as other implementations may include different features than the one described above.

### BRIEF DESCRIPTION OF THE DRAWINGS

FIG. 1 is a block diagram of a system according to an implementation.

FIG. 2 is a flow chart illustrating a method according to an implementation.

FIG. 3 is an equivalent circuit diagram for illustrating various implementations.

FIG. 4 is a diagram of a transistor usable in some implementations.

FIG. 5 is a diagram illustrating a relationship between internal resistance of a transistor and junction temperature.

FIG. 6 is a diagram illustrating signals of some implementations.

FIGS. 7 to 13 are diagrams illustrating signals according to some implementations.

### DETAILED DESCRIPTION

In the following, various implementations will be described in detail referring to the attached drawings. These implementations are provided as examples only and are not to be construed as limiting.

Details, variations and modifications described with respect to one of the implementations may also be applied to other implementations and are therefore not to be construed as limiting.

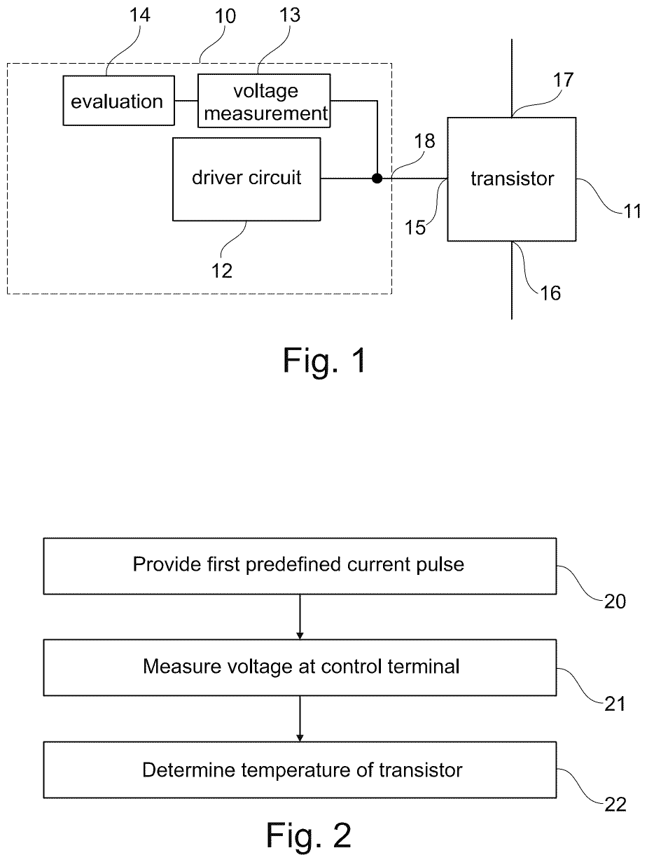

FIG. 1 is a block diagram of a system according to an implementation, including a transistor driver device 10 according to an implementation and a transistor 11. Generically, a transistor as used herein is described as including a control terminal 15 and two load terminals 16, 17. As example, in some of the following implementations insulated gate bipolar transistors (IGBTs) where control terminal 15 is a gate terminal and the first and second load terminal 16, 17 are an emitter terminal and a collector terminal, respectively, are used. However, implementations are not limited to IGBTs, and for example field effect transistors, where control terminal 15 corresponds to a gate terminal, load terminal 16 corresponds to a source terminal and load terminal 17 corresponds to a drain terminal may also be used.

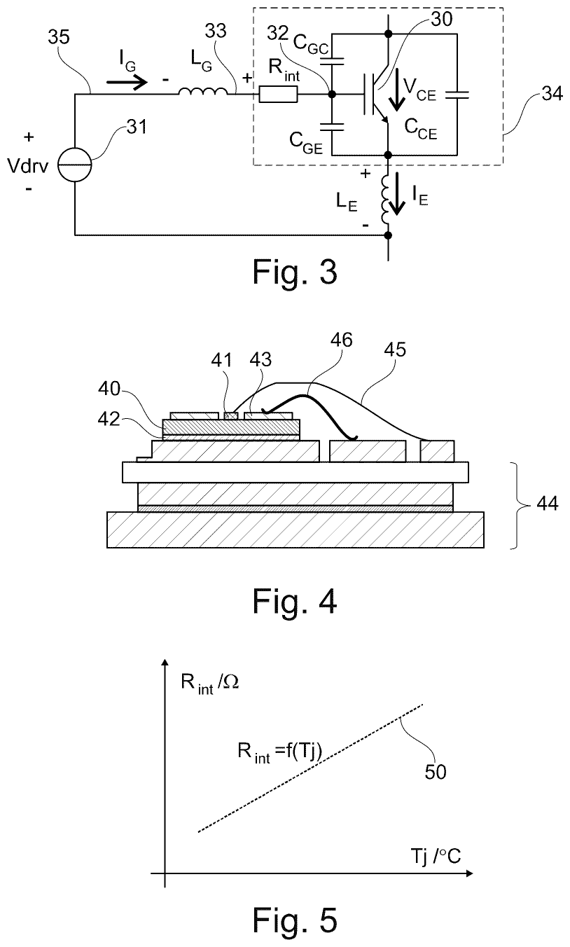

Transistor driver device 10 includes a driver circuit 12. Driver circuit 12 in the implementation of FIG. 1 is a current source based driver, as explained later in more detail with respect to FIG. 3, which delivers a current to control terminal 15 to charge or discharge control terminal 15 with respect to load terminal 16, to establish a corresponding gate-source or gate-emitter voltage to control transistor 11. A current source based driver circuit means that a current source is used to deliver a predefined or controlled gate current, instead of using a voltage source together with a gate resistor in a voltage source based driver.

While for simplicity driver circuit 12 is shown as only connected to the control terminal 15 via a driver output terminal 18, as will be shown below, the driver circuit may be additionally connected to load terminal 16 or an auxiliary load terminal as a return path and reference.

Driver circuit 12 may be operated to turn transistor 11 on and off, essentially as in conventional driver circuits, by charging or discharging control terminal 15.

Furthermore, for measuring a temperature of transistor 11, driver circuit 12 may be configured to provide a current pulse of a predefined duration and current to control terminal 15. The duration and current may be independent from the type of transistor used, whereas for example otherwise a current for turning transistor 11 on or off may be dependent on the type of transistor. This current pulse will be also referred to as first current pulse hereinafter.

It should be noted that providing a current may include providing a positive current for charging control terminal 15 or a negative current for discharging control terminal 15. Depending on transistor type, one of the charging or discharging may turn transistor 11 on, and the other one of charging or discharging may turn transistor 11 off. In some of the following examples, it will be assumed that charging control terminal 15, e.g., providing a current from driver circuit 12 to control terminal 15, turns transistor 11 on, and discharging control terminal 15, e.g., providing a current from control terminal 15 to driver circuit 12, turns transistor 11 off.

As will be explained below in more detail, the first current pulse may be part of a turning on of transistor 11, part of a turning off of transistor 11, or may be provided outside a switching operation of transistor 11. The first current pulse may transfer a charge amount to or from control terminal 15 which alone is not sufficient to switch transistor 11 between its on and off state. For switching transistor 11, the first current pulse may be combined with a second current pulse, which may for example be longer than the current pulse, and/or have a different current magnitude, and may be adapted to the type of transistor, and in combination with the first current pulse may provide sufficient charge transfer for switching the transistor.

Transistor driver device 10 additionally comprises a voltage measurement device 13. Voltage measurement device 13 is configured to measure a voltage at the driver output terminal 18. The measured voltage approximately corresponds to a voltage at control terminal 15 because in operation of the system control terminal 15 is coupled to driver output terminal 18 with a low ohmic connection. In other implementations, a separate measurement input of transistor driver device 10 coupled to control terminal 15 may be used. In some implementations, a voltage measurement device may be provided directly at control terminal 15, and the measured voltage may be provided to an evaluation device 14 explained further below. In some cases, this may increase accuracy by avoiding effects of the connection between driver output terminal 18 and control terminal 15, but requires the voltage measurement device to be provided directly at control terminal 15. In the following, the term “measuring the voltage at control terminal 15” will be used, with the understanding that this voltage may be measured entirely in driver device 10 by voltage measurement circuit 13 coupled to driver output terminal 18 as shown.

Measuring a voltage at control terminal 15 is to be understood as measuring the potential difference between control terminal 15 and a reference potential. In some implementations, the reference potential is a voltage at load terminal 16, for example source voltage for a field effect transistor or emitter voltage for an IGBT. In some implementations, transistor 11 may include an auxiliary load terminal, for example auxiliary emitter terminal or auxiliary source terminal, coupled to transistor driver device 10 and providing a return path for the current provided to control terminal 15. In this case, the reference voltage may be a voltage at such an auxiliary load terminal, as measured in transistor driver device 10 using voltage measurement circuit 13. In yet other implementations, the reference voltage may be a fixed reference voltage like ground.

To measure the temperature of transistor 11, the voltage at control terminal 15 is measured concurrently with applying the first current pulse. Based on the measured voltage, then evaluation device 14 determines the temperature. In particular, in this way for example a peak voltage at control terminal 15 while applying the first current pulse may be determined, and the temperature may be determined based on this peak voltage. For example, evaluation device 14 may determine the temperature based on calibration data like a calibration curve or a lookup table, which translates the measured voltage to a temperature. For such a calibration procedure, the temperature of transistor 11 may be measured by other means, for example by a temperature sensor thermally coupled to transistor 11 and/or incorporated in transistor 11 for calibration purposes.

While driver circuit 12, voltage measurement device 13 and evaluation device 14 are shown as separate blocks in FIG. 1, two or more may be integrated in a common circuit on a common chip. In other implementations, several chips may be used. In yet other implementations, evaluation device 14 may be provided remotely and receives the voltage measurement data from voltage measurement device 13 via some communication connection like a wire based connection or a wireless connection. The evaluation device may be implemented in hardware and/or software. In a hardware implementation, the evaluation device can be embodied, for example, as a computer or as a microprocessor. Thus, the evaluation device may include one or more processors. In a software implementation, the evaluation device can be embodied as a computer program product, as a function, as a routine, as an algorithm, as part of a program code or as an executable object.

FIG. 2 is a flow chart illustrating a method according to an implementation, which may be implemented in the system of FIG. 1, but is not limited thereto. Nevertheless, to avoid repetitions, the method of FIG. 2 will be explained referring to FIG. 1.

At 20, the method comprises providing a first current pulse to a control terminal of a transistor, for example by driver circuit 12 of FIG. 1 as explained above. At 21, the method comprises measuring a voltage at the control terminal of the transistor concurrently with applying the first current pulse, as explained with respect to voltage measurement device 13 of FIG. 1. At 22, the method comprises determining the temperature of the transistor based on the measured voltage.

To explain further, FIG. 3 shows a simplified equivalent circuit of a current source driver as used in an some implementations. FIG. 4 illustrates a schematic view of a corresponding transistor.

As an example, an insulated gate bipolar transistor (IGBT) 34 is used in FIG. 3, which may be implemented as an IGBT chip 40 mounted to a base 44, including for example a DBC (direct bonded copper) plate, which in turn is provided on a base plate. A collector terminal 42 of IGBT chip 40 may be directly provided on DBC plate, and a gate terminal 41 and an emitter terminal 43 may be coupled using bond wires 45, 46.

IGBT 34 is illustrated as an equivalent circuit with a core IGBT 30, which represents an ideal IGBT without parasitics, a collector-emitter capacitance C_{CE}, a gate-collector capacitance C_{GC}, a gate-emitter capacitance C_{GE}, and an internal resistance Rᵢₙₜ between a gate terminal 33 of IGBT 34 and a gate node 32 of core IGBT 30. This internal resistance Rᵢₙₜ in practical cases dominates the overall resistance between a driver, represented by a current source, and internal gate node 32, such that the resistance e.g., caused by a bond wire like bond wire 45 coupling the driver to gate terminal 33 may be neglected in the discussions below.

Returning to FIG. 3, a current source 31 provides a gate current I_{G} to a gate terminal 33 of IGBT 34, which may be gate pad 41 of IGBT chip 40 of FIG. 4. As mentioned above, the gate current I_{G} may be positive or negative. In other implementations, a field effect transistor like a MOSFET may be used.

The gate current IG is provided to internal gate node 32 via an inductance LG, which may for example predominantly include an inductivity of a bond wire used, like bond wire 45, and may also include an inductivity of other circuit paths, and internal resistance Rint between gate terminal 33 and internal gate node 32, which as explained above dominates the resistance between driver (e.g., current source 31) and internal gate node 32. For example, IGBT 30 may include trench gate structures that are connected to the gate pad (e.g., 41) via a gate runner and internal resistance Rint, for example. We note that internal resistance Rint may be caused by a different structure and/or material than the gate pad, the gate runner and/or the gate structure, such as gate trenches.

A voltage between collector and emitter of core IGBT 30 is labelled V_{CE}, a current flowing from the emitter terminal is labelled I_{E}, and an inductance of a connection to the source terminal, which offers a return path for current source 31, is labelled L_{E}. For switching transistor 30, inter alia the gate emitter capacitance C_{GE} is charged or discharged by gate current I_{G}.

The internal resistance Rᵢₙₜ is temperature dependent. For example, in an operating range the dependency may be essentially linear, as shown by a curve 50 of FIG. 5, which shows the internal resistance Rᵢₙₜ over the junction temperature T_{J}. Other dependencies may also exist depending on transistor implementation.

In good approximation, the internal resistance Rᵢₙₜ multiplied with the gate current I_{G} corresponds to a voltage Vdrv across the current source 31. This voltage in turn, for a given reference potential at the emitter terminal, corresponds to the voltage at gate terminal 33 in FIG. 3, which essentially corresponds to measuring the voltage at driver output terminal 18 shown in FIG. 1, as Rᵢₙₜ is internal to IGBT 34 and a resistance of a connection to the driver like a resistance of bond wire 45 may be neglected in comparison. The inductance L_{G} is mainly caused by the electrical connection, for example bond wire, between the transistor driver device 10 and the transistor like transistor 11. This is unlike the situation in voltage source based drivers, where an external gate resistor must be provided which dominates the resistance between driver and transistor, in contrast to the present case of a current source driver where the internal resistance dominates.

When the current pulse is predefined, therefore from the above relationship between voltage, current and internal resistance the internal resistance Rᵢₙₜ may be determined. Rᵢₙₜ in turn has a clear relation to the junction temperature, as shown in FIG. 5. By using a current pulse of predefined current magnitude and length and measuring the voltage, the temperature may be determined.

If the voltage at gate terminal 33 is V1 and the voltage at internal gate node 34 is V2, then Rᵢₙₜ=(V1−V2)/I_{G}. Furthermore, the gate current charges the gate-emitter capacitance C_{GE} thus building up V2, according to V2=(I_{G}×t)/C_{GE}, where t is the duration of the gate current. Combining the two equations leads to Rᵢₙₜ=V1/I_{G}−t/C_{GE}.

This means that for a certain transistor having a certain fixed C_{GE}, when the above-mentioned first predefined current pulse of predefined current magnitude, e.g., predefined I_{G}, and predefined duration, e.g., predefined t, is applied, V2 is fixed by this pulse, and variations of V1 depend only on variations of Rᵢₙₜ. Therefore, by measuring V1, e.g., the voltage at gate terminal 33, a measure of Rᵢₙₜ and thus of the temperature Tj (see FIG. 5) may be obtained.

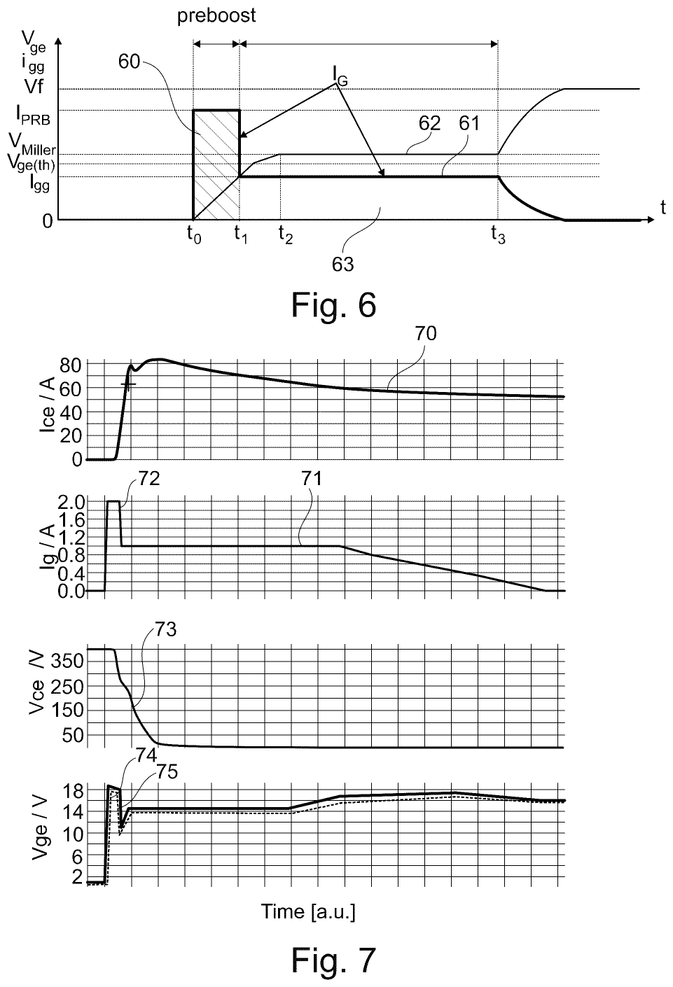

FIG. 6 illustrates an example of using the above mentioned first current pulse of predefined current magnitude and predefined length together with a second current pulse during turning on of a transistor. A curve 61 in FIG. 6 shows the gate current during a turn on procedure, and a curve 62 illustrates the gate emitter voltage. At a time t₀ and to a time t₁, a first current pulse 60 is applied with a current level I_{PRB} and a duration from t₀ to t₁. This first current pulse may have a duration of 100 to 150 nanoseconds, but is not limited thereto. At the end of the first current pulse 60, the gate emitter voltage of curve 62 is still below the threshold voltage V_{ge(th)}, such that the first current pulse 60 does not turn the transistor on.

After the first current pulse, a second current pulse 63 is applied, which has a lower current I_{gg} and a longer duration, essentially from t₁ to t₃, than the first current pulse. Within a short time after t₁, the gate emitter voltage reaches the threshold voltage V_{ge(th)} and then the Miller plateau voltage V_{Miller}. After t₃, the voltage then rises to the full voltage V_{f}, and the gate current according to curve 61 decreases to zero, meaning that the gate is fully charged.

FIG. 7 shows simulation results for a situation as shown in FIG. 6 turning on an IGBT. A curve 70 shows the collector emitter current of the transistor, a curve 71 shows the gate current (similar to curve 61 of FIG. 6), a curve 73 shows the collector emitter voltage, and curves 74, 75 show the gate emitter voltage.

The gate current includes a first current pulse 72, as explained referring to FIG. 6 for first current pulse 60. In response to current pulse 72, the gate emitter voltage also exhibits a peak. Curve 74 shows the case for a junction temperature of 150° C., and curve 75 illustrates the case for a junction temperature of 25° C. As can be seen, the voltages differ and therefore may serve as a measure for the junction temperature. For measurement, for example the maximum gate emitter voltage during first current pulse 72, or a gate emitter voltage at the end of first current pulse 72, an average gate emitter voltage during first current pulse 72 or another clearly defined voltage may be used.

It should be noted that while single curves 70 and 73 for collector-emitter current and collector-emitter-voltage are shown, these curves may vary slightly with temperature, which, however, does not affect the temperature measurement discussed herein and has therefore been omitted from FIG. 7 and the following Figures.

During the first predefined current pulse, the transistor as explained above is below its threshold, e.g., not turned on, and no load current flows. Measurement with different current magnitudes in the second current pulse for different turn-on speeds show that the voltage Vge measured concurrently with the first predefined current pulse are independent of such different second current pulses. They are also independent from the load current flowing after the transistor is turned on.

As mentioned above, the relationship between this voltage thus measured and the junction temperature may be obtained via calibration.

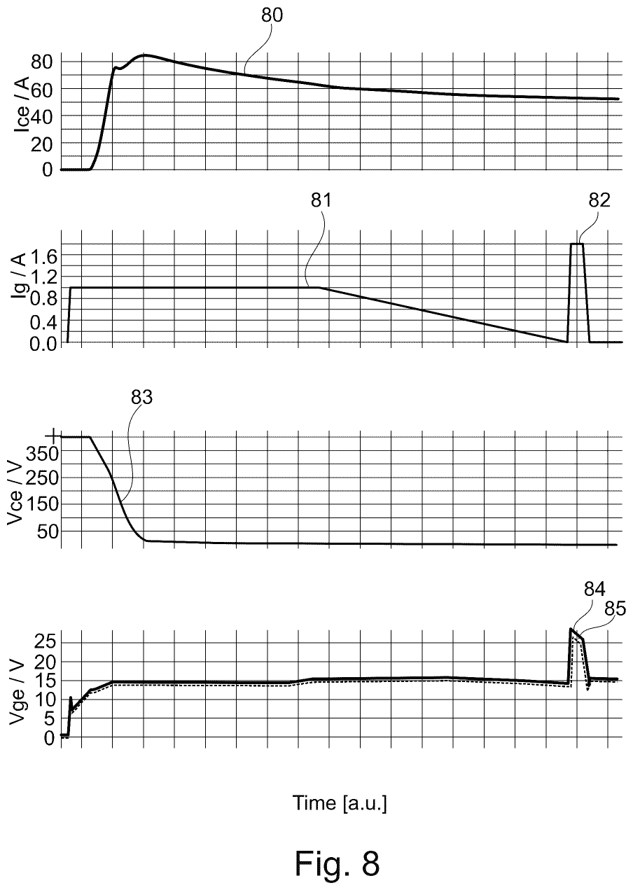

In the examples of FIGS. 6 and 7, the current pulse occurs at the start of a turning on of the transistor. This is not limiting, and further possibilities will now be explained referring to FIGS. 8 to 12, 13A and 13B. FIGS. 8 to 12, 13A and 13B show curves for the same quantities as FIG. 7, namely the collector emitter current Ice, the gate current Ig, the collector emitter voltage Vce, and the gate emitter voltage V_{ge}, e.g., the voltage measured for example by voltage measurement device 13 of FIG. 1.

In FIG. 8, a curve 80 shows the collector emitter current, a curve 81 shows the gate current, a curve 83 shows the collector emitter voltage. The gate emitter voltage is shown for two different temperatures. In the example of FIG. 8, a first current pulse 82 is provided at the end of the gate current flowing for turning on the transistor, e.g., after the corresponding second current pulse. A curve 84 illustrates a case for a temperature of 150° C. junction temperature, and curve 85 shows a case for a junction temperature of 25° C. Therefore, also here by measuring the voltage during the current pulse 82, the junction temperature may be determined. Similar to FIG. 7, for measurement, for example the maximum gate emitter voltage during first current pulse 82, or a gate emitter voltage at the end of first current pulse 82, an average gate emitter voltage during first current pulse 82 or another clearly defined voltage may be used.

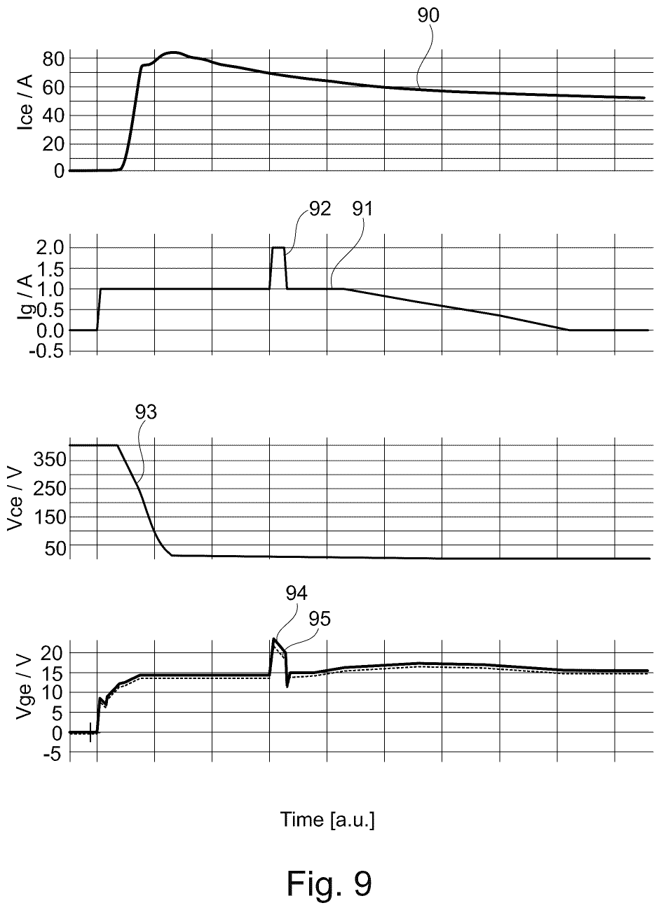

FIG. 9 shows a further example for a turn on, and a curve 90 shows the collector emitter current, a curve 91 shows the gate current, a curve 93 shows the collector emitter voltage and curves 94, 95 show the gate emitter voltage for two different temperatures. In FIG. 9, a first current pulse 92 is provided approximately in the middle of the turning on, e.g., in the middle of the second current pulse. Curve 94 shows the response for a junction temperature of 150° C., and curve 95 shows the response, e.g., the gate emitter voltage, or a junction temperature of 25° C. Also here, by measuring the voltage concurrently with the current pulse, the temperature may therefore by determined. Similar to FIG. 7, for measurement, for example the maximum gate emitter voltage during first current pulse 92, or a gate emitter voltage at the end of first current pulse 92, an average gate emitter voltage during first current pulse 92 or another clearly defined voltage may be used.

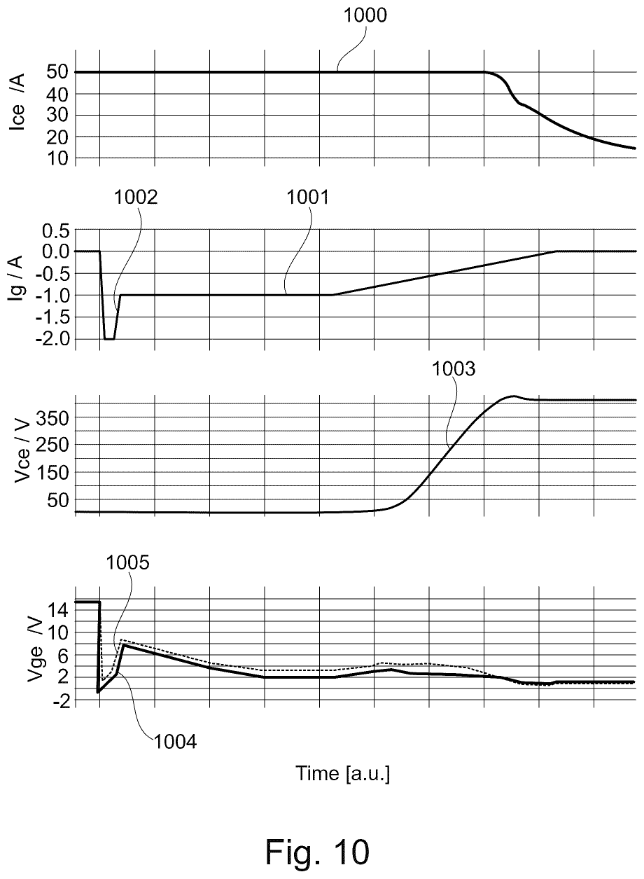

FIGS. 7 to 9 show examples for applying a first current pulse in the course of turning on the transistor. Next, examples for applying the current pulse in the course of turning off the transistor will be explained referring to FIGS. 10 to 12. A curve 1000 illustrates the collector emitter current, a curve 1001 the gate current, a curve 1003 the collector emitter voltage, and curves 1004, 1005 the gate emitter voltage. In this case, a first current pulse 1002 and the second current pulse provide a negative current for discharging the gate, such that the transistor is turned off, the collector emitter voltage rises to the corresponding blocking voltage and the collector emitter current decreases. In the example of FIG. 10, similar to FIG. 7, the current pulse 1002 is at the start of the turning off.

Curve 1004 shows the response for a junction temperature of 150° C., and curve 1005 shows the response for 25° C. junction temperature. As can be seen, also here a clear dependency of the gate emitter voltage from the temperature exists, and by measuring the voltage the junction temperature may be determined. Similar to FIG. 7, for measurement, for example the maximum gate emitter voltage during first current pulse 1002, or a gate emitter voltage at the end of first current pulse 1002, an average gate emitter voltage during first current pulse 1002 or another clearly defined voltage may be used.

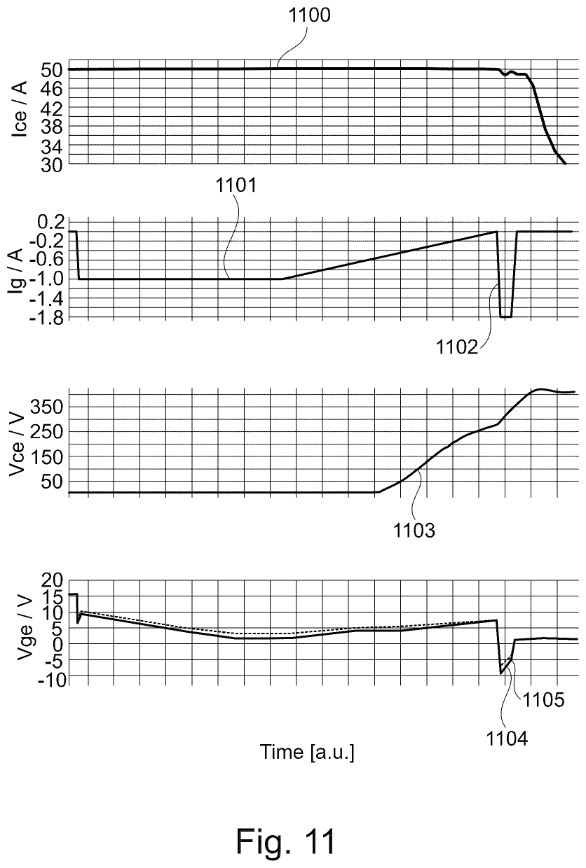

In FIG. 11, a curve 1100 shows the collector emitter current, a curve 1101 shows the gate current, a curve 1103 shows the collector emitter voltage and curves 1104, 1105 show the gate emitter voltage. In this case, the first current pulse 1102, again with a negative current for turning off the transistor, is provided at the end of the turning off, e.g., after the second current pulse. Curve 1104 shows the gate emitter voltage for a junction temperature of 150° C., and curve 1105 shows the gate emitter voltage for a junction temperature of 25° C. Also here, measuring the voltage allows determining of the junction temperature. Similar to FIG. 7, for measurement, for example the maximum gate emitter voltage during first current pulse 1102, or a gate emitter voltage at the end of first current pulse 1102, an average gate emitter voltage during first current pulse 1102 or another clearly defined voltage may be used.

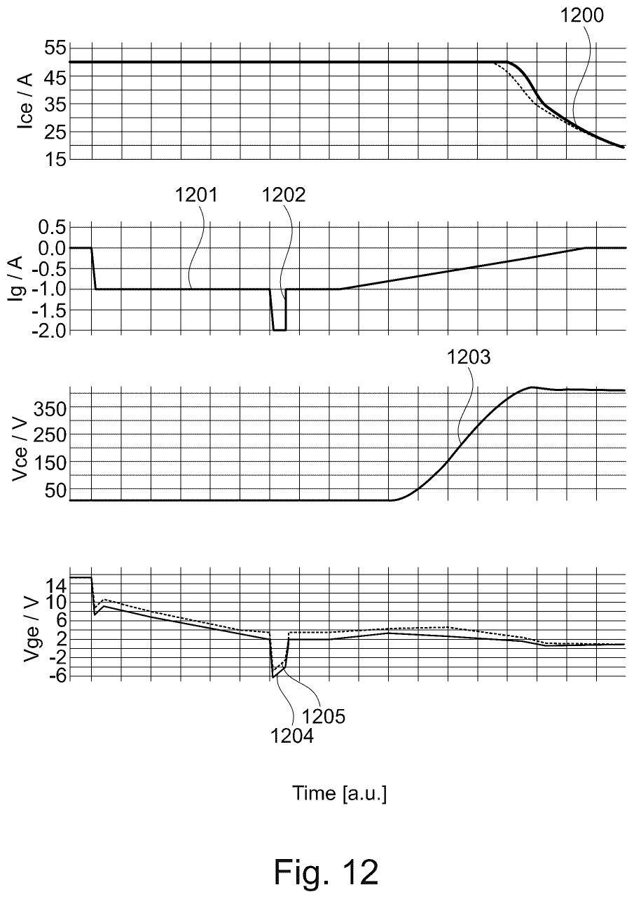

In FIG. 12, a curve 1200 shows the collector emitter current, a curve 1201 shows the gate current, a curve 1203 shows the collector emitter voltage, and curves 1204, 1205 show the gate emitter voltage. Here, the first current pulse 1202 is provided approximately in the middle of the second current pulse, or, in other words, approximately in the middle of the turn off procedure (similar to FIG. 9, where the first current pulse was provided approximately in the middle of the turning on of the transistor). Curve 1204 shows a gate emitter voltage for a junction temperature of 150° C., and curve 1205 shows the gate emitter voltage for a junction temperature of 25° C. Also here, by measuring the voltage the temperature may be determined.

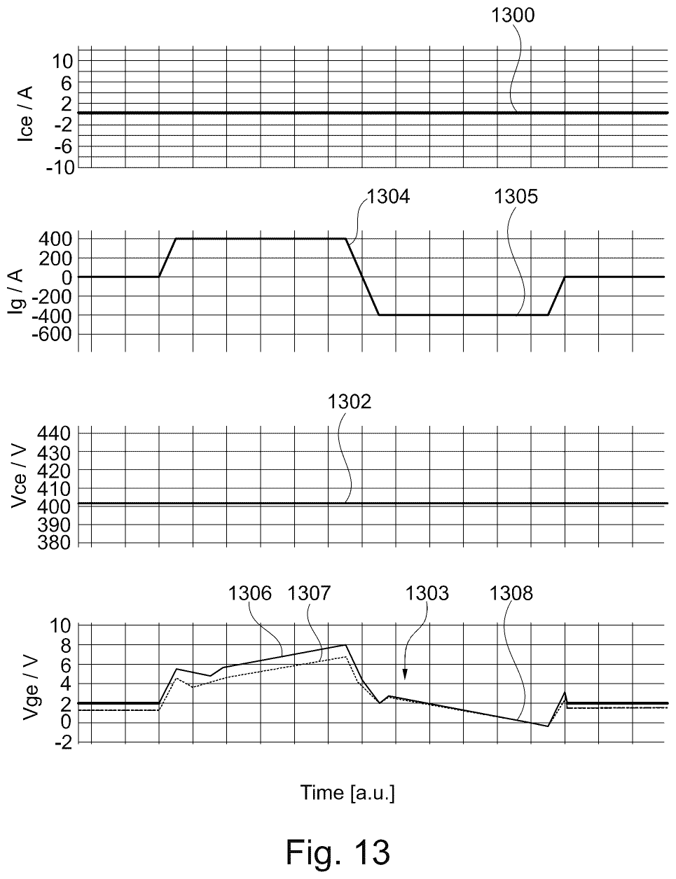

FIGS. 13 shows a further example where the first current pulse takes place while the transistor is turned off, e.g., outside a switching event of the transistor. In FIG. 13, a curve 1300 shows the collector emitter current, a curve 1301 shows the gate current, a curve 1302 shows the collector emitter current, and curves 1303 show the gate emitter voltage. In the example of FIG. 13, the first current pulse includes a first sub-pulse 1304 and a second sub-pulse 1305.

In the example of FIG. 13, the first and second sub-pulses 1304, 1305 have the same duration, e.g., around 60 ns, and same current magnitudes, but with opposite signs. The first sub-pulse 1304 has a positive current thus charging the gate, and the second sub-pulse 1305 has a negative current, thus discharging the gate. As duration and current magnitude are equal, after the first and second sub-pulses 1304, 1305 the gate charge essentially is the same as before the first and second sub-pulses 1304, 1305. It should be noted that in other implementations the duration and current magnitude may not be the same, and still the charge may be preserved, as long as the integral of current over time for the first sub-pulse is minus the integral of current over time for the second sub-pulse, e.g., the same amount of charged is transferred by both sub-pulses 1304, 1305. As a simple example, in another implementation second sub-pulse 1305 may have a duration twice the duration of the first sub-pulse 1304, but half the current magnitude. Same amount of charge or equal charge may mean equal or the same within some tolerance, e.g., 10%.

The gate emitter voltage may be measured concurrently with the first sub-pulse. A curve 1306 shows a case for a junction temperature of 150° C., and a curve 1307 a case for a junction temperature of 25° C.

While in FIG. 13 the first and second sub-pulses are applied while the transistor is switched off, in other implementations the sub-pulses may be applied while the transistor is switched on. In this case, first a negative current may be applied in a first sub-pulse, and then a positive current may be applied to restore the charge. The voltage may again be measured during the first sub-pulse. In each case, the sub-pulses are selected such that these do not change the state of the transistor (turned off or turned on).

### Aspects

Some implementations will be defined by the following aspects:

Aspect 1. A method of determining a temperature of a transistor, comprising: providing a current pulse of predefined length and predefined current magnitude to a control terminal of the transistor, measuring a voltage at the control terminal, and determining the temperature of the transistor based on the measured voltage.

Aspect 2. The method of aspect 1, wherein determining the temperature comprises determining the temperature based on the measured voltage and calibration data indicating a relationship between the measured voltage and the temperature.

Aspect 3. The method of aspect 1 or 2, wherein a duration of the current pulse is 200 ns or less.

Aspect 4. The method of any one of aspects 1 to 3, wherein a charge transferred by the current pulse is below a threshold charge required to change a switching state of the transistor between on and off.

Aspect 5. The method of any of aspects 1 to 4, wherein the current pulse comprises a first sub-pulse and a second sub-pulse, wherein a current direction of the first sub-pulse is opposite to a current direction of the second sub-pulse.

Aspect 6. The method of aspect 5, wherein a total charge transferred by the first sub-pulse is equal to a total charge transferred by the second sub-pulse.

Aspect 7. The method of aspect 5 or 6, wherein a current magnitude of the first sub-pulse is equal to a current magnitude of the second sub-pulse, and wherein a time duration of the first sub-pulse is equal to a time duration of the second sub-pulse.

Aspect 8. The method of any one of aspects 1 to 7, wherein the measured voltage is a peak voltage caused by the current pulse.

Aspect 9. The method of any one of aspects 1 to 8, wherein the voltage is measured concurrently with the current pulse.

Aspect 10. The method of any one of aspects 1 to 9, wherein the current pulse is provided at a time outside switching events of the transistor.

Aspect 11. The method of aspect 10, wherein the time outside switching events of the transistor is a time when the transistor is turned off.

Aspect 12. The method of any one of aspects 1 to 9, wherein the current pulse is a first current pulse, wherein the method further comprises providing a second current pulse, wherein a length of the second current pulse is longer that the length of the first current pulse, and/or a current magnitude of the second current pulse is lower than the current magnitude of the first current pulse.

Aspect 13. The method of aspect 12, wherein the predefined length and predefined current magnitude of the first current pulse are fixed independent of type of the transistor, and wherein the length and current magnitude of the second current pulse are selected based on the type of the transistor.

Aspect 14. The method of aspect 12 or 13, wherein a total charge transferred by the first current pulse and the second current pulse is above a threshold charge required to change a switching state of the transistor between on and off.

Aspect 15. The method of any one of aspects 12 to 14, wherein the first current pulse is provided before, after or during the second current pulse.

Aspect 16. A transistor driver device, comprising: a driver circuit configured to provide a current pulse of predefined length and predefined current magnitude at a driver output terminal; a voltage measurement device configured to measure a voltage between the driver output terminal and a reference potential; and an evaluation device configured to determine a temperature of a transistor based on the measured voltage.

Aspect 17. The transistor driver device of aspect 16, configured to perform the method of any one of aspects 1 to 15.

Aspect 18. A system, comprising: the transistor driver device of aspect 16 or 17; and the transistor, wherein the driver output terminal is coupled to a control terminal of the transistor.

Aspect 19. An evaluation device, configured to receive a voltage measured concurrently with a current pulse of predefined length and predefined current magnitude at a control terminal at a transistor, and to determine a temperature of the transistor based on the measured voltage.

Aspect 20. A system, comprising: the evaluation device of aspect 19; a transistor; a driver circuit configured to provide the current pulse of predefined length and predefined current magnitude to the control terminal; and a voltage measurement device configured to measure the voltage at the control terminal and to provide the measured voltage to the evaluation device.

Although specific implementations have been illustrated and described herein, it will be appreciated by those of ordinary skill in the art that a variety of alternate and/or equivalent implementations may be substituted for the specific implementations shown and described without departing from the scope of the present implementation. This application is intended to cover any adaptations or variations of the specific implementations discussed herein. Therefore, it is intended that this implementation be limited only by the claims and the equivalents thereof.

1. A method of determining a temperature of a transistor, comprising:
providing a current pulse of a predefined length and a predefined current magnitude to a control terminal of the transistor;
measuring a voltage at the control terminal; and
determining the temperature of the transistor based on the measured voltage.

2. The method of claim 1, wherein determining the temperature comprises determining the temperature based on the measured voltage and based on calibration data indicating a relationship between the measured voltage and the temperature.

3. The method of claim 1, wherein a duration of the current pulse is 200 ns or less.

4. The method of claim 1, wherein a charge transferred by the current pulse is below a threshold charge required to change a switching state of the transistor between on and off.

5. The method of claim 1,
wherein the current pulse comprises a first sub-pulse and a second sub-pulse, and
wherein a current direction of the first sub-pulse is opposite to a current direction of the second sub-pulse.

6. The method of claim 5, wherein a total charge transferred by the first sub-pulse is equal to a total charge transferred by the second sub-pulse.

7. The method of claim 5,
wherein a current magnitude of the first sub-pulse is equal to a current magnitude of the second sub-pulse, and
wherein a time duration of the first sub-pulse is equal to a time duration of the second sub-pulse.

8. The method of claim 1, wherein the measured voltage is a peak voltage caused by the current pulse.

9. The method of claim 1, wherein the voltage at the control terminal is measured concurrently with the current pulse.

10. The method of claim 1, wherein the current pulse is provided at a time outside switching events of the transistor.

11. The method of claim 10, wherein the time outside switching events of the transistor is a time when the transistor is turned off.

12. The method of claim 1, wherein the current pulse is a first current pulse
wherein the method further comprises providing a second current pulse, and
wherein a length of the second current pulse is longer that the predefined length of the first current pulse, and/or a current magnitude of the second current pulse is less than the predefined current magnitude of the first current pulse.

13. The method of claim 12,
wherein the predefined length and predefined current magnitude of the first current pulse are fixed independent of type of the transistor, and
wherein the length and current magnitude of the second current pulse are selected based on the type of the transistor.

14. The method of claim 12, wherein a total charge transferred by the first current pulse and the second current pulse is above a threshold charge required to change a switching state of the transistor between on and off.

15. The method of claim 12, wherein the first current pulse is provided before, after, or during the second current pulse.

16. A transistor driver device, comprising:
a driver circuit configured to provide a current pulse of a predefined length and a predefined current magnitude at a driver output terminal;
a voltage measurement device configured to measure a voltage between the driver output terminal and a reference potential; and
an evaluation device configured to determine a temperature of a transistor based on the measured voltage.

17. The transistor driver device of claim 16, wherein a charge transferred by the current pulse is below a threshold charge required to change a switching state of the transistor between on and off.

18. A system, comprising:
a transistor:
a driver circuit configured to provide a current pulse of a predefined length and a predefined current magnitude at a driver output terminal, wherein the driver output terminal is coupled to a control terminal of the transistor:
a voltage measurement device configured to measure a voltage between the driver output terminal and a reference potential; and
an evaluation device configured to determine a temperature of the transistor based on the measured voltage.

19. (canceled)

20. (canceled)

21. The transistor driver device of claim 16, wherein the current pulse comprises a first sub-pulse and a second sub-pulse, and
wherein a current direction of the first sub-pulse is opposite to a current direction of the second sub-pulse.

22. The transistor driver device of claim 16, wherein the current pulse is a first current pulse,
wherein the driver circuit is configured to provide a second current pulse, and
wherein a length of the second current pulse is longer that the predefined length of the first current pulse, and/or a current magnitude of the second current pulse is less than the predefined current magnitude of the first current pulse.
